(19) United States
(12) Patent Application Publication
(10) Pub. No.: US 2024/0405057 A1
(43) Pub. Date: Dec. 5, 2024

(54) SEMICONDUCTOR STRUCTURE, MANUFACTURING METHOD THEREOF, AND LIGHT-EMITTING DEVICE

(71) Applicant: Enkris Semiconductor (Wuxi), Ltd., Wuxi (CN)

(72) Inventor: Kai CHENG, Wuxi (CN)

(73) Assignee: Enkris Semiconductor (Wuxi), Ltd., Wuxi (CN)

(21) Appl. No.: 18/432,935

(22) Filed: Feb. 5, 2024

(30) Foreign Application Priority Data
May 31, 2023 (CN) 202310637185.6

(51) Int. Cl. H01L 27/15; B82Y 20/00; H01L 33/50; H01L 33/60

(52) U.S. Cl. CPC H01L 27/156; H01L 33/502; H01L 33/60; B82Y 20/00; H01L 2933/0041

(57) ABSTRACT

Disclosed are a semiconductor structure, a manufacturing method of a semiconductor structure, and a light-emitting device. The semiconductor structure includes: a light-emitting structure including a plurality of light-emitting units, where an insulating structure is disposed between adjacent two light-emitting units; and a light-control layer, disposed on a side of the light-emitting structure, including a plurality of light-control regions regularly disposed and a substrate structure disposed between adjacent two light-control regions, one light-control region corresponding to at least one light-emitting unit, where the substrate structure includes a growth substrate layer structure and an etching stop layer structure stacked along a direction away from the light-emitting structure.

### CROSS-REFERENCE TO RELATED APPLICATIONS

This disclosure claims priority to Chinese Patent Application No. 202310637185.6, filed on May 31, 2023, which is hereby incorporated by reference in its entirety.

### TECHNICAL FIELD

The present disclosure relates to the field of semiconductor technologies, and in particular, to a semiconductor structure, a manufacturing method of a semiconductor structure, and a light-emitting device.

### BACKGROUND

Micro light-emitting diode (Micro-LED) technology, also known as LED micro-display technology, combines reducing the volume and weight of overall system, and reducing manufacturing costs, with advantages such as low power consumption, high light use efficiency, fast response speed, wide working temperature range, and strong anti-interference ability compared to traditional LED display technology.

However, the LED micro-display technology still has some technical challenges at present. For example, during a substrate stripping process, it is usually unavoidable to cause damage to an epitaxial structure and cause stress release, which causes mechanical fragmentation of an epitaxial layer, generates micro defects, and then affects the lattice quality of quantum well regions, thereby causing a decrease in optical performance and affecting yield.

### SUMMARY

In view of this, embodiments of the present disclosure provide a semiconductor structure, a manufacturing method of a semiconductor structure, and a light-emitting device, to solve a technical problem of epitaxial structure damage during a substrate stripping process in conventional technologies.

According to a first aspect of the present disclosure, an embodiment of the present disclosure provides a semiconductor structure, including: a light-emitting structure including a plurality of light-emitting units, where an insulating structure is disposed between adjacent two light-emitting units; and a light-control layer, disposed on a side of the light-emitting structure, including a plurality of light-control regions regularly disposed and a substrate structure disposed between adjacent two light-control regions, one light-control region corresponding to at least one light-emitting unit, where the substrate structure includes a growth substrate layer structure and an etching stop layer structure stacked along a direction away from the light-emitting structure.

As an optional embodiment, a material of the growth substrate layer structure includes silicon, and a material of the etching stop layer structure includes silicon germanium.

As an optional embodiment, a thickness of the growth substrate layer structure is less than or equal to 50 μm.

As an optional embodiment, a thickness of the etching stop layer structure is 10-100 nm.

As an optional embodiment, the light-control region includes an opening filled with photoresist and quantum dots.

As an optional embodiment, a surface of the light-emitting structure exposed by the opening has an uneven structure.

As an optional embodiment, the light-control region includes a porous structure filled with quantum dots.

As an optional embodiment, the porous structure is a single-layer structure, and the porous structure is a porous silicon oxide layer.

As an optional embodiment, the porous structure is a double-layer structure, and the porous structure includes a porous silicon oxide layer and a porous silicon germanium oxide layer disposed on a side, away from the light-emitting structure, of the porous silicon oxide layer.

As an optional embodiment, a sidewall of the light-control region is inclined, so that an equivalent diameter of the light-control region increases along a direction of light travel.

As an optional embodiment, a light reflection layer is disposed on a sidewall of the light-control region.

According to a second aspect of the present disclosure, an embodiment of the present disclosure provides a light-emitting device including: the semiconductor structure according to any one of embodiments of the first aspect and a driving circuit, where the driving circuit is connected with the semiconductor structure to drive the semiconductor structure to emit light.

According to a third aspect of the present disclosure, an embodiment of the present disclosure provides a manufacturing method of a semiconductor structure including the following steps:
S1: providing a substrate including a support substrate layer, an etching stop layer, and a growth substrate layer stacked in sequence;
S2: forming a light-emitting structure on the growth substrate layer, where the light-emitting structure includes a plurality of light-emitting units, and an insulating structure is disposed between adjacent two light-emitting units;
S3: etching the substrate from a side, away from the growth substrate layer, to the etching stop layer; and
S4: forming a light-control layer by forming a plurality of light-control regions regularly disposed in the etching stop layer and the growth substrate layer, where the light-control layer further includes a substrate structure disposed between adjacent two light-control regions, and the substrate structure includes the growth substrate layer structure and the etching stop layer structure stacked along a direction away from the light-emitting structure, and one light-control region corresponds to at least one light-emitting unit.

As an optional embodiment, the step S4 includes:
S411: preparing a plurality of openings regularly disposed on a side, away from the light-emitting structure, of the etching stop layer, the plurality of openings running through the growth substrate layer and the etching stop layer; and
S412: filling the plurality of openings with photoresist and quantum dots, or filling the plurality of openings with photoresist, to form the light-control region.

As an optional embodiment, the quantum dots include at least one of red quantum dots, green quantum dots, and blue quantum dots.

As an optional embodiment, the step S4 includes:
S421: preparing a window on a side, away from the light-emitting structure, of the etching stop layer, the window running through the etching stop layer;
S422: preparing holes on a side of the growth substrate layer exposed by the window, the holes running through the growth substrate layer, and oxidizing material between adjacent holes to form a plurality of porous structures regularly disposed; and
S423: filling all of the plurality of porous structures with quantum dots, or filling part of the plurality of porous structures with quantum dots, to form the light-control region.

As an optional embodiment, the porous structure is a single-layer structure, and the porous structure is a porous silicon oxide layer.

As an optional embodiment, the step S4 includes:
S431: preparing holes on a side, away from the light-emitting structure, of the etching stop layer, the holes running through the etching stop layer and the growth substrate layer; and oxidizing material between adjacent holes to form a plurality of porous structures regularly disposed; and
S432: filling all of the plurality of porous structures with quantum dots, or filling part of the plurality of porous structures with quantum dots, to form the light-control region.

As an optional embodiment, the porous structure is a double-layer structure, and the porous structure includes a porous silicon oxide layer and a porous silicon germanium oxide layer disposed on a side, away from the light-emitting structure, of the porous silicon oxide layer.

As an optional embodiment, a sidewall of the light-control region is inclined, so that an equivalent diameter of the light-control region increases along a direction of light travel.

### BRIEF DESCRIPTION OF THE DRAWINGS

FIG. 1a to FIG. 1f are schematic diagrams of a semiconductor structure according to some embodiments of the present disclosure.

FIG. 2a to FIG. 2d are schematic diagrams of a semiconductor structure according to some embodiments of the present disclosure.

FIG. 3 is a schematic diagram of a semiconductor structure according to an embodiment of the present disclosure.

FIG. 4 is a schematic diagram of a semiconductor structure according to another embodiment of the present disclosure.

FIG. 5 is a schematic diagram of a semiconductor structure according to another embodiment of the present disclosure.

FIG. 6 is a schematic diagram of a semiconductor structure according to another embodiment of the present disclosure.

FIG. 7 is a schematic diagram of a semiconductor structure according to another embodiment of the present disclosure.

FIG. 8 is a schematic diagram of a semiconductor structure according to another embodiment of the present disclosure.

FIG. 9 is a schematic flowchart of a manufacturing method of a semiconductor structure according to an embodiment of the present disclosure.

FIG. 10 is a schematic diagram of an intermediate structure of a semiconductor structure according to an embodiment of the present disclosure.

FIG. 11a to FIG. 11c are schematic diagrams of changes of Ge component in an etching stop layer.

FIG. 12 is a schematic diagram of an intermediate structure of a semiconductor structure according to another embodiment of the present disclosure.

FIG. 13 is a schematic flowchart of a manufacturing method of a semiconductor structure according to another embodiment of the present disclosure.

FIG. 14 is a schematic diagram of an intermediate structure of a semiconductor structure according to another embodiment of the present disclosure.

FIG. 15 is a schematic diagram of an intermediate structure of a semiconductor structure according to another embodiment of the present disclosure.

FIG. 16 is a schematic diagram of an intermediate structure of a semiconductor structure according to another embodiment of the present disclosure.

FIG. 17 is a schematic diagram of an intermediate structure of a semiconductor structure according to another embodiment of the present disclosure.

FIG. 18 is a schematic diagram of an intermediate structure of a semiconductor structure according to another embodiment of the present disclosure.

FIG. 19 is a schematic flowchart of a manufacturing method of a semiconductor structure according to another embodiment of the present disclosure.

FIG. 20 is a schematic diagram of an intermediate structure of a semiconductor structure according to another embodiment of the present disclosure.

FIG. 21 is a schematic flowchart of a manufacturing method of a semiconductor structure according to another embodiment of the present disclosure.

FIG. 22 is a schematic diagram of an intermediate structure of a semiconductor structure according to another embodiment of the present disclosure.

FIG. 23 is a schematic diagram of an intermediate structure of a semiconductor structure according to another embodiment of the present disclosure.

FIG. 24 is a schematic flowchart of a manufacturing method of a semiconductor structure according to another embodiment of the present disclosure.

FIG. 25 is a schematic diagram of an intermediate structure of a semiconductor structure according to another embodiment of the present disclosure.

FIG. 26 is a schematic diagram of a light-emitting device according to an embodiment of the present disclosure.

### DETAILED DESCRIPTIONS OF THE EMBODIMENTS

A clear and complete description of technical solutions in embodiments of the present disclosure is given below with reference to the drawings of the embodiments of the present disclosure; apparently, the described embodiments are only a part, but not all of the embodiments of the present disclosure. All of the other embodiments that may be obtained by those skilled in the art based on the embodiments in the present disclosure without any inventive effort fall into the protection scope of the present disclosure.

To solve a technical problem of epitaxial structure damage during a substrate stripping process in conventional technologies, the present disclosure provides a semiconductor structure, a manufacturing method of a semiconductor structure, and a light-emitting device. The semiconductor structure includes: a light-emitting structure including a plurality of light-emitting units, where an insulating structure is disposed between adjacent two light-emitting units; and a light-control layer, disposed on a side of the light-emitting structure, including a plurality of light-control regions regularly disposed and a substrate structure disposed between adjacent two light-control regions, one light-control region corresponding to at least one light-emitting unit, where the substrate structure includes a growth substrate layer structure and an etching stop layer structure stacked along a direction away from the light-emitting structure. On the one hand, the etching stop layer structure disclosed can effectively control the thickness of the remaining substrate after thinning, reduce the overall thickness of the device, protect the light-emitting structure during the thinning process, and reduce the damage to the epitaxial structure caused by substrate stripping, thereby improving the application performance of semiconductor structures. On the other hand, the etching stop layer structure and the growth substrate layer structure can be served as a light blocking wall between adjacent two light-control regions, thereby ensuring uniform light output, good directionality, high light extraction rate for each light-control region, and further avoiding light crosstalk.

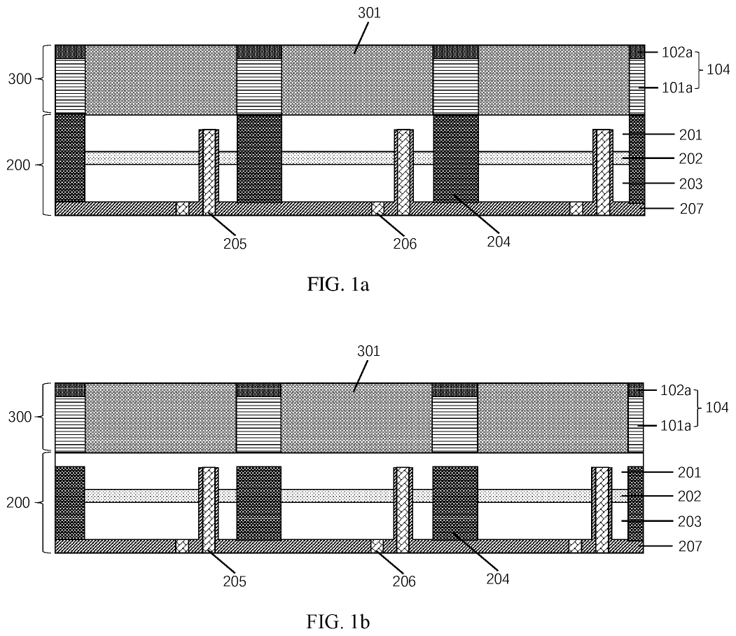

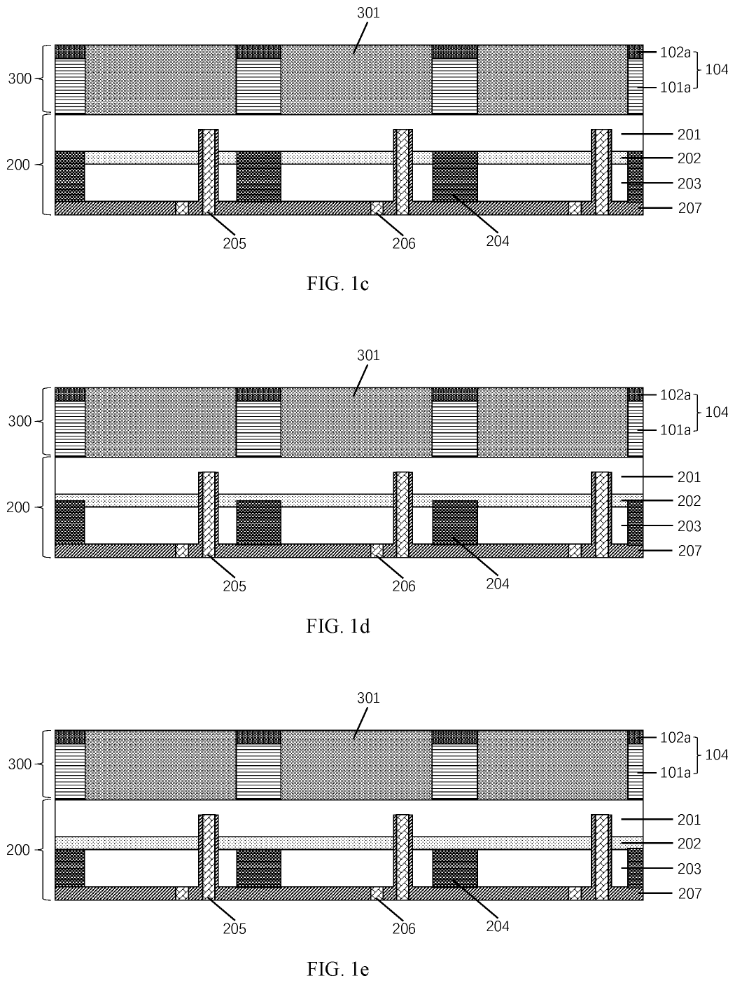

A semiconductor structure, a manufacturing method of a semiconductor structure and a light-emitting device in the present disclosure are further illustrated below with reference to FIG. 1 to FIG. 26.

FIG. 1a is a schematic diagram of a semiconductor structure according to an embodiment of the present disclosure. As shown in FIG. 1a, the semiconductor structure includes a light-emitting structure 200 including a plurality of light-emitting units, where an insulating structure 204 is disposed between adjacent two light-emitting units; and a light-control layer 300 disposed on a side of the light-emitting structure 200. The light-control layer 300 includes a plurality of light-control regions 301 regularly disposed and a substrate structure 104 disposed between adjacent two light-control regions 301. At least one light-emitting unit corresponds to one light-control region 301. Along a direction away from the light-emitting structure 200, the substrate structure 104 includes a growth substrate layer structure 101a and an etching stop layer structure 102a stacked.

In an embodiment, as shown in FIG. 1a, the light-emitting structure 200 includes a first semiconductor layer 201, an active layer 202, a second semiconductor layer 203, and at least one set of first electrode 205 and second electrode 206. The first electrode 205 is connected with the first semiconductor layer 201, and is blocked from the second semiconductor layer 203 and the active layer 202 through an insulating material 207. The second electrode 206 is connected with the second semiconductor layer 203, and is blocked from the first electrode 205 through the insulating material 207. The light-emitting structure 200 includes a plurality of light-emitting units, and an insulation structure 204 is disposed between adjacent two light-emitting units. A thickness of the insulation structure 204 is less than or equal to a thickness of the light-emitting structure 200. Each light-control region 301 corresponds to at least one light-emitting unit.

In an embodiment, as shown in FIG. 1a, the insulation structure 204 completely penetrates the first semiconductor layer 201 from a side, away from the light-control layer 300, of the second semiconductor layer 203, so that the adjacent two light emitting units are isolated with each other and non-radiative recombination at edges is reduced. Other embodiments can also achieve this technical effect, for example, the insulation structure 204 may partially penetrate the first semiconductor layer 201, as shown in FIG. 1b; or the insulation structure 204 may completely penetrate the active layer 202, as shown in FIG. 1c; or the insulation structure 204 may partially penetrate the active layer 202, as shown in FIG. 1d; or the insulation structure 204 may completely penetrate the second semiconductor layer 203, as shown in FIG. 1e; or the insulation structure 204 may partially penetrate the second semiconductor layer 203, as shown in FIG. 1f.

In an embodiment, a thickness of the growth substrate layer structure 101a is less than or equal to 50 μm, and a thickness of the etching stop layer structure 102a is 10-100 nm. A material of the growth substrate layer structure 101a includes silicon, a material of the etching stop layer structure 102a includes silicon germanium, the material of the growth substrate layer structure 101a and the etching stop layer structure 102a is opaque and may be served as a light blocking wall between adjacent two light-control regions 301, thereby ensuring uniform light output, good directionality, and high light extraction rate for each light-control region 301, and further avoiding light crosstalk.

In an embodiment, one light-control region 301 corresponds to one light emitting unit, as shown in FIG. 1a. In other embodiments, one light-control region 301 may correspond to several light-emitting units, and when one light-emitting unit is disconnected, the other light-emitting units can still emit light normally, which avoids the common “bad spot” problem in the display field. The present disclosure is not specific limited to the number of light-emitting units corresponding to the light-control region 301, as long as the light-control region 301 corresponds to at least one light-emitting unit. The number of light-emitting units corresponding to the light-control region 301 may be selected according to application requirements of specific devices.

In some embodiments, a light-control region 301 includes an opening 302 filled with photoresist and quantum dots, and the quantum dots include at least one of red quantum dots, green quantum dots, and blue quantum dots.

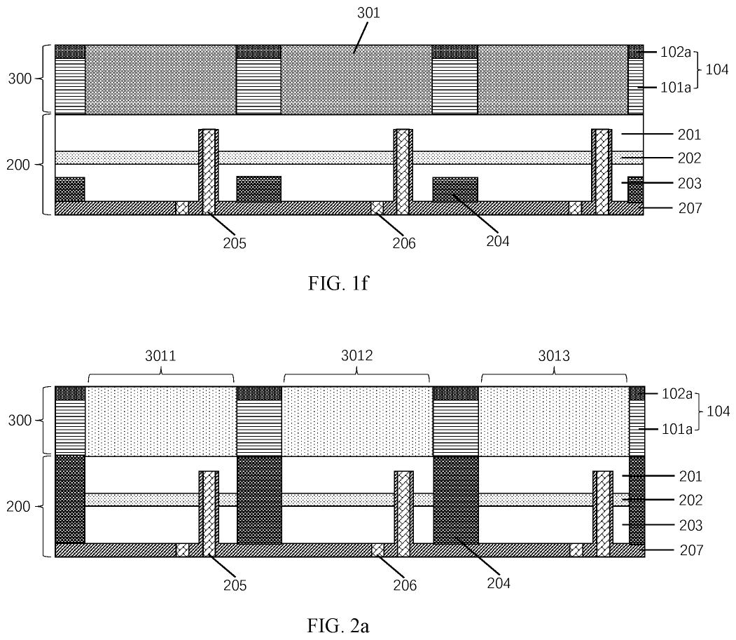

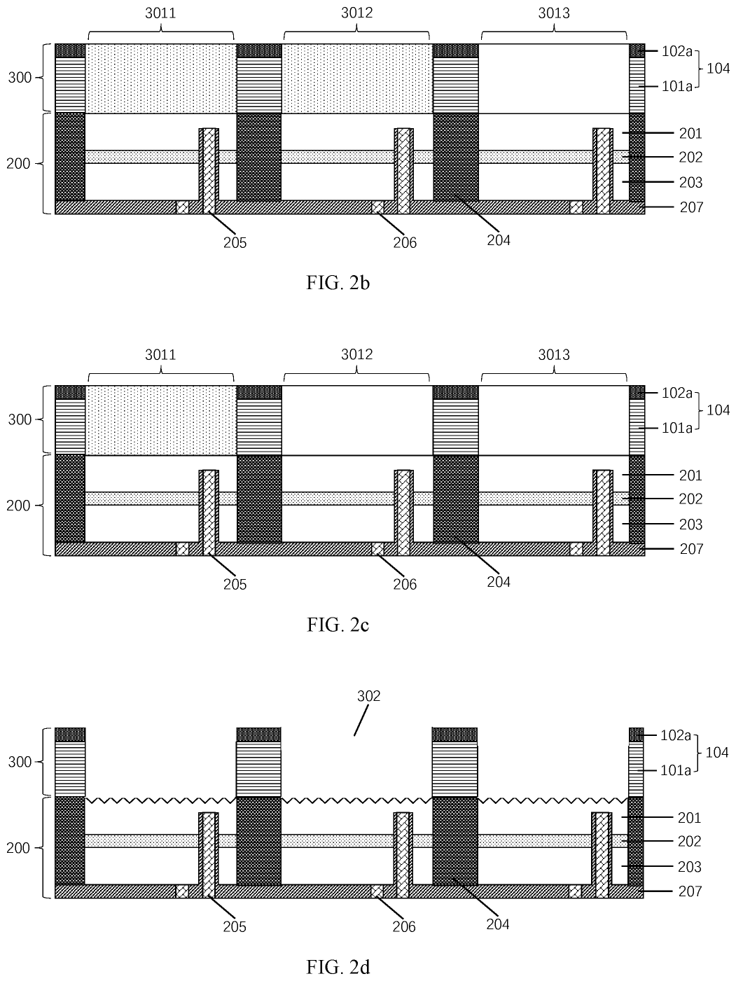

Specifically, FIG. 2a to FIG. 2d are schematic diagrams of a semiconductor structure according to some embodiments of the present disclosure. Optionally, the light emitted by the light-emitting structure 200 may be white light; as shown in FIG. 2a, a part of openings 302 of light-control regions 301 are filled with photoresist and red quantum dots, to form red light regions 3011; a part of the openings 302 are filled with photoresist and green quantum dots, to form green light regions 3012; a part of the openings 302 are filled with photoresist and blue quantum dots, to form blue light regions 3013, thereby forming three primary colors and achieving a full color LED. Optionally, the light emitted by the light-emitting structure 200 may be blue light; as shown in FIG. 2b, a part of openings 302 of the light-control regions 301 are filled with photoresist and red quantum dots, to form red light regions 3011; a part of the openings 302 are filled with photoresist and green quantum dots, to form green light regions 3012; a part of the openings 302 are filled with photoresist, to form blue light regions 3013, thereby forming three primary colors and achieving a full color LED. Optionally, the light emitted by the light-emitting structure 200 may be green light and blue light; as shown in FIG. 2c, a part of openings 302 of the light-control regions 301 are filled with photoresist and red quantum dots, to form red light regions 3011; a part of the openings 302 are filled with photoresist, to form green light regions 3012; a part of the openings 302 are filled with photoresist, to form blue light regions 3013, thereby forming three primary colors and achieving a full color LED.

In some embodiments, a surface of the light-emitting structure 200 exposed by the opening 302 has an uneven structure (as shown in FIG. 2d). Understandably, after the formation of the opening 302, a part of the first semiconductor layer 201 of the semiconductor structure is exposed. Preferably, the exposed part of the first semiconductor layer 201 may be roughened or patterned (as shown in FIG. 2d), and then photoresist and quantum dots are filled in the opening 302, making the semiconductor structure fully colored while further improving the light extraction rate of the semiconductor structure. The present disclosure is not specific limited to the method of roughening or patterning and shapes in the embodiments.

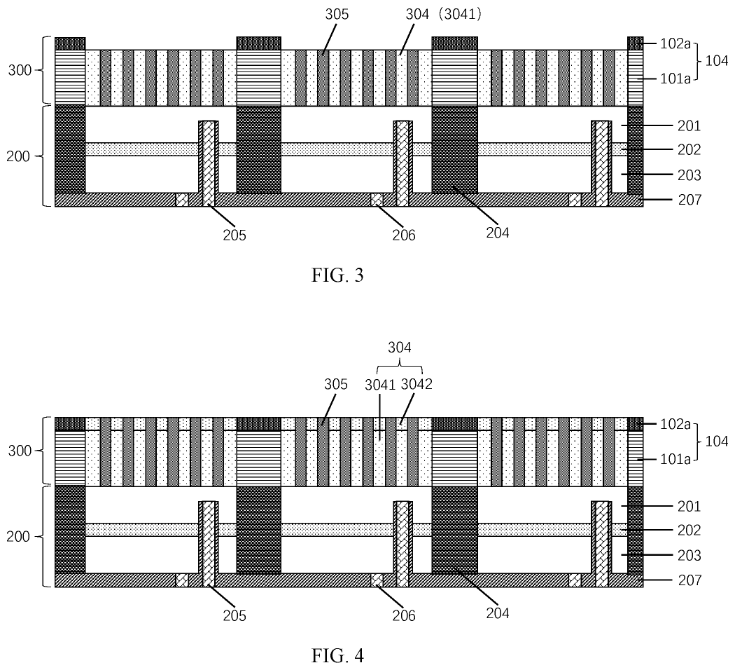

In some embodiments, the light-control region 301 includes a porous structure 304 filled with quantum dots. FIG. 3 is a schematic diagram of a semiconductor structure according to an embodiment of the present disclosure. As shown in FIG. 3, the porous structure 304 is a single layer structure, and the porous structure 304 is a porous silicon oxide layer 3041. The porous structure 304 and the growth substrate layer structure 101a are prepared from a same epitaxial layer, and the porous structure 304 is formed by preparing holes from the material of the growth substrate layer structure 101a and oxidizing.

FIG. 4 is a schematic diagram of a semiconductor structure according to another embodiment of the present disclosure. As shown in FIG. 4, the porous structure 304 is a double-layer structure, and the porous structure 304 includes a porous silicon oxide layer 3041 and a porous silicon germanium oxide layer 3042 disposed on a side, away from the light-emitting structure 200, of the porous silicon oxide layer 3041. The porous silicon oxide layer 3041 and the growth substrate layer structure 101a are prepared from a same epitaxial layer, and the porous silicon germanium oxide layer 3042 and the etching stop layer structure 102a are prepared from a same epitaxial layer. The porous silicon oxide layer 3041 is formed by preparing holes from the material of the growth substrate layer structure 101a and oxidizing, and the porous silicon germanium oxide layer 3042 is formed by preparing holes from the material of the etching stop layer structure 102a and oxidizing.

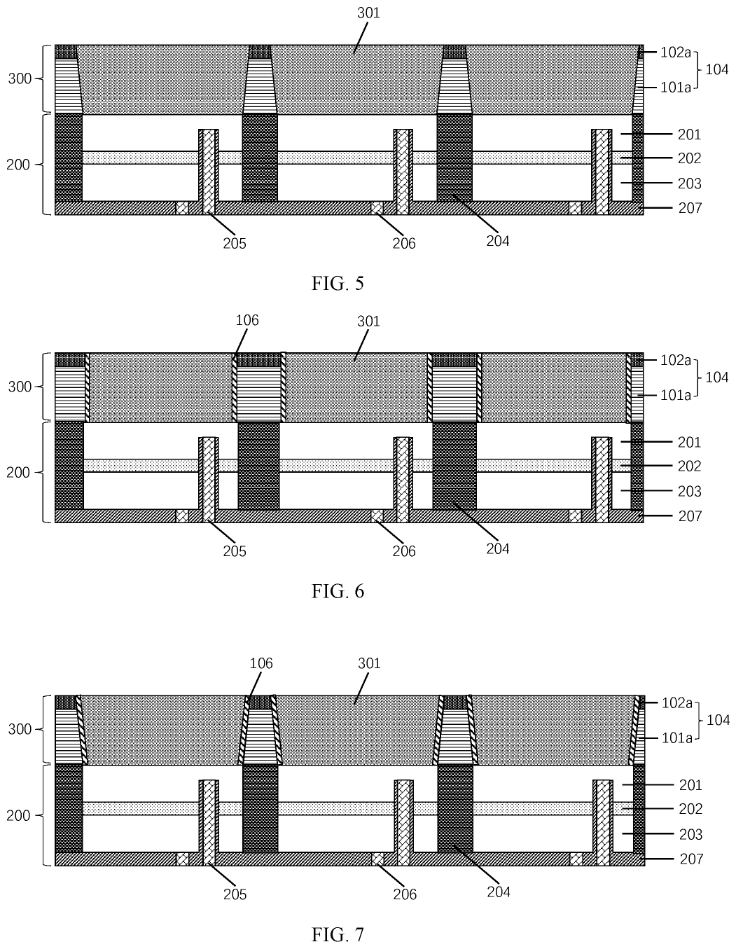

FIG. 5 is a schematic diagram of a semiconductor structure according to another embodiment of the present disclosure. As shown in FIG. 5, a sidewall of the light-control region 301 is inclined, so that an equivalent diameter of the light-control region 301 increases along a direction of light travel. Due to the inclined sidewall of the light-control region 301, the equivalent diameter of a space surrounded by the inclined sidewall increases in the direction of light travel, thereby improving the light extraction efficiency of semiconductor devices.

FIG. 6 is a schematic diagram of a semiconductor structure according to another embodiment of the present disclosure. A light reflection layer 106 is disposed on a sidewall of a light-control region 301, as shown in FIG. 6, the material of the light reflective layer 106 may be one of silver, aluminum, nickel or other metals that reflect light, or a metal alloy or metal combination layer composed of several metals, or an alloy super-lattice structure. The design of the light reflective layer 106 can further improve the light output efficiency of devices.

FIG. 7 is a schematic diagram of a semiconductor structure according to another embodiment of the present disclosure. As shown in FIG. 7, a sidewall of the light-control region 301 is inclined, so that an equivalent diameter of the light-control region 301 increases along a direction of light travel, and a light reflection layer 106 is disposed on the sidewall of the light-control region 301, thereby further improving the light output efficiency of devices.

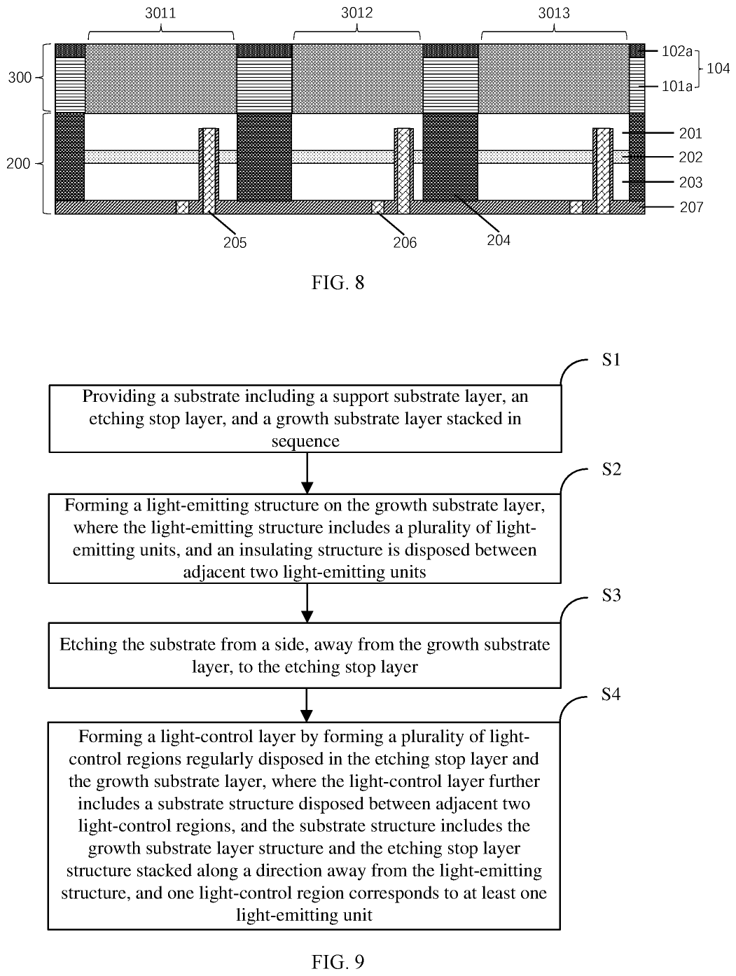

In some embodiments, projection areas, on a plane where the substrate 100 is disposed, of a plurality of light-control regions 301 are the same or different. Human eyes are the most sensitive to a green light spectral region with a wavelength of 555 nm, and for a longer wavelength (such as red light) or a shorter wavelength (such as blue light), the sensitivity of the human eyes reduces, which means that higher radiant power is required in these wavelength regions to present a same brightness perception. By changing the area size of regions with different colors of light, the quantum dot content of the regions with different colors of light may be changed, thereby adjusting the brightness perception of regions with different light-emitting wavelength. FIG. 8 is a schematic diagram of a semiconductor structure according to another embodiment of the present disclosure. As shown in FIG. 8, the projection area of a red light region 3011 and a blue light region 3013 is larger than the projection area of a green light region 3012, thereby improving the brightness perception of red light and blue light.

According to another aspect of the present disclosure, the present disclosure provides a manufacturing method of a semiconductor structure. FIG. 9 is a schematic flowchart of a manufacturing method of a semiconductor structure according to an embodiment of the present disclosure. As shown in FIG. 9, the manufacturing method includes the following steps.

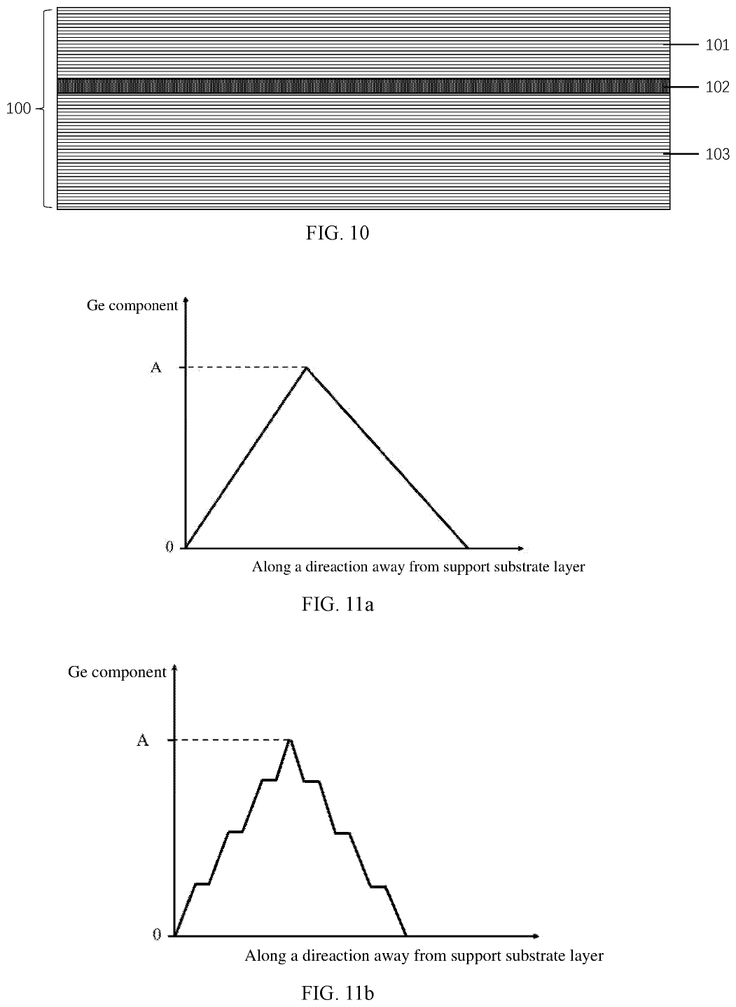

Step S1: Providing a substrate 100 including a support substrate layer 103, an etching stop layer 102, and a growth substrate layer 101 stacked in sequence (as shown in FIG. 10).

In an embodiment, the material of the growth substrate layer 101 and the support substrate layer 103 includes Si, and the material of the etching stop layer 102 includes SiGe. Along a direction away from the support substrate layer 103, Ge component in the etching stop layer 102 increases from 0 at the beginning of growth to a maximum value A, and then decreases to 0 at the end of growth, and a range of A is 10%-90%. Along the direction away from the support substrate layer 103, a change mode, from the beginning of growth to the maximum, of the Ge component in the etching stop layer 102 is one or a combination of continuous increasing, step increasing, or oscillating increasing. Along the direction away from the support substrate layer 103, a change mode, from the maximum to the end of growth, of the Ge component in the etching stop layer 102 is one or a combination of continuous decreasing, step decreasing, or oscillating decreasing. Specifically, FIG. 11a to FIG. 11c are schematic diagrams of changes of Ge component in an etching stop layer. As shown in FIG. 11a, along the direction away from the support substrate layer 103, the change mode, from 0 at the beginning of growth to the maximum, of Ge component in a SiGe etching stop layer 102 is continuous increasing, and then the change mode, from the maximum to 0, of the Ge component is continuous decreasing. As shown in FIG. 11b, along the direction away from the support substrate layer 103, the change mode, from 0 at the beginning of growth to the maximum, of the Ge component in the etching stop layer 102 is step increasing, and then the change mode, from the maximum to 0, of the Ge component is step decreasing. As shown in FIG. 11c, along the direction away from the support substrate layer 103, the change mode, from 0 at the beginning of growth to the maximum, of the Ge component in the etching stop layer 102 is oscillating increasing, and then the change mode, from the maximum to 0, of the Ge component is oscillating decreasing.

In this embodiment, the etching stop layer 102 with Ge component increasing first and then decreasing is set between the support substrate layer 103 and the growth substrate layer 101; on the one hand, it can ensure the etching accuracy of etching to the etching stop layer 102 and control the thickness of the remaining substrate; on the other hand, by designing the change of Ge component in the etching stop layer 102, it is possible to ensure that there is no component jump between the etching stop layer 102 and the support substrate layer 103 that is in contact with a lower surface of the etching stop layer 102, and between the etching stop layer 102 and the growth substrate layer 101 that is in contact with an upper surface of the etching stop layer 102, so that the transition between material compositions becomes smooth, growth dislocations can be reduced, and the material quality of the subsequent epitaxial layer can be ensured.

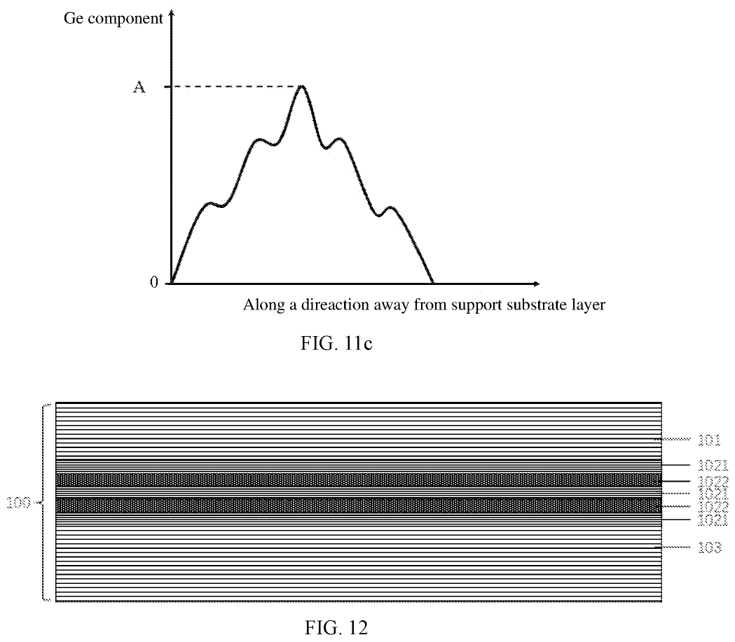

In some embodiments, FIG. 12 is a schematic diagram of an intermediate structure of a semiconductor structure according to another embodiment of the present disclosure. As shown in FIG. 12, the etching stop layer 102 is a periodic structure composed of a first layer 1021 and a second layer 1022 alternately arranged. A material of the first layer 1021 includes Si, and a material of the second layer 1022 includes SiGe. A layer, which is contacted with the support substrate layer 103, of the etching stop layer 102 is the first layer 1021, and a layer, which is contacted with the growth substrate layer 101, of the etching stop layer 102 is the second layer 1022. The material of the first layer 1021, the growth substrate layer 101, and the support substrate layer 103 are Si, without component jump. The thicknesses of the first layer 1021 and the second layer 1022 are constant and the same or different; or the thickness of the first layer 1021 remains constant, but the thickness of the second layer 1022 changes; or the thickness of the first layer 1021 changes, but the thickness of the second layer 1022 remains constant. Each cycle of the etching stop layer 102 includes one first layer 1021 and one second layer 1022, and the number of cycles of the etching stop layer 102 is 2-20. By designing the cycles and the thickness of each layer of the etching stop layer 102, the stress distribution in the substrate 100 can be adjusted, and the crystal quality of the substrate 100 can be improved, thereby improving the crystal quality of each epitaxial layer on the substrate 100.

Step S2: Forming a light-emitting structure 200 on the growth substrate layer 101, where the light-emitting structure 200 includes a plurality of light-emitting units, and an insulating structure 204 is disposed between adjacent two light-emitting units.

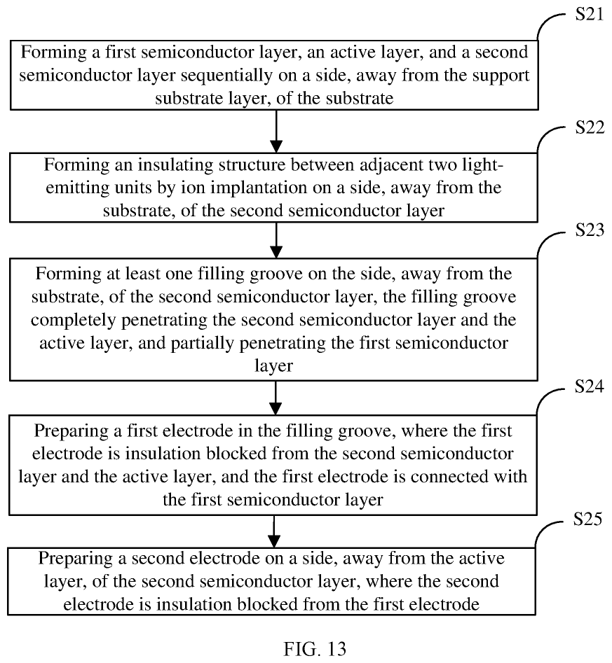

The light-emitting structure 200 includes a first semiconductor layer 201, an active layer 202, a second semiconductor layer 203, at least one set of first electrode 205 and second electrode 206. Specifically, as shown in FIG. 13, the Step S2 may include the following steps.

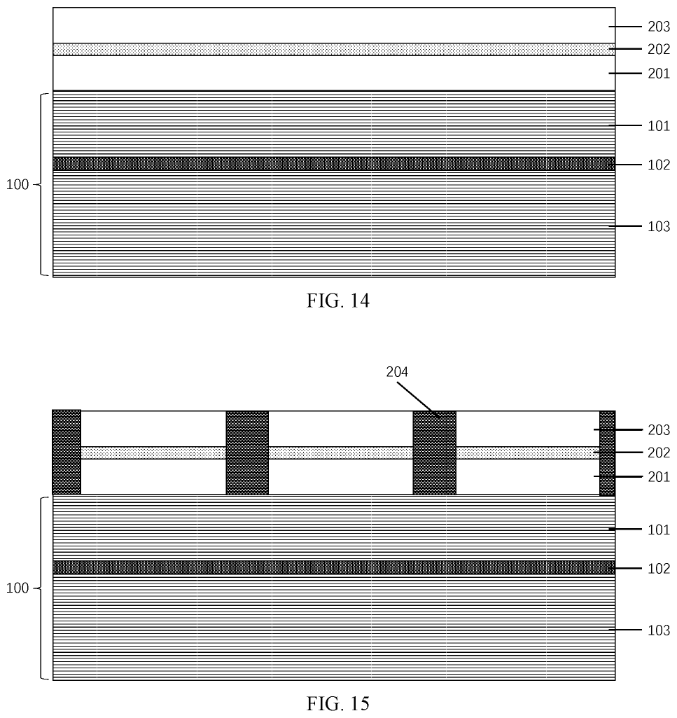

Step S21: Forming a first semiconductor layer 201, an active layer 202, and a second semiconductor layer 203 sequentially on a side, away from the support substrate layer 103, of the substrate 100 (As shown in FIG. 14).

Step S22: Forming an insulating structure 204 between adjacent two light-emitting units by ion implantation on a side, away from the substrate 100, of the second semiconductor layer 203 (As shown in FIG. 15).

The implanted ions include at least one of hydrogen ion, helium ion, nitrogen ion, and fluorine ion. Optionally, the method of forming the insulation structure 204 between adjacent two light-emitting units may be to etch a groove between the adjacent light-emitting units and filling the groove with insulating material 207, which is not limited to the present disclosure.

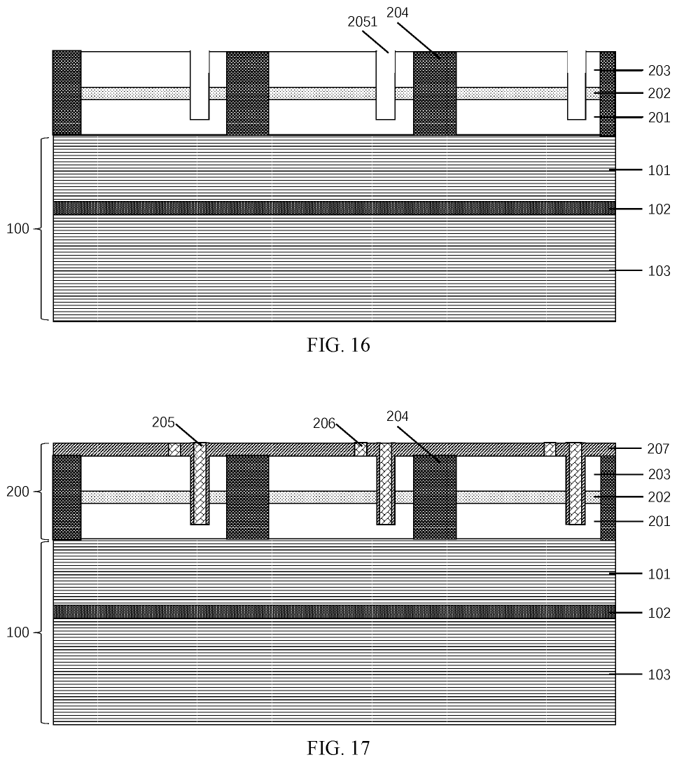

Step S23: Forming at least one filling groove 2051 on the side, away from the substrate 100, of the second semiconductor layer 203, the filling groove 2051 completely penetrating the second semiconductor layer 203 and the active layer 202, and partially penetrating the first semiconductor layer 201 (as shown in FIG. 16).

Step S24: Preparing a first electrode 205 in the filling groove 2051, where the first electrode 205 is insulation blocked from the second semiconductor layer 203 and the active layer 202, and the first electrode 205 is connected with the first semiconductor layer 201.

Step S25: Preparing a second electrode 206 on a side, away from the active layer 202, of the second semiconductor layer 203, where the second electrode 206 is insulation blocked from the first electrode 205.

FIG. 17 is a schematic diagram of an intermediate structure of a semiconductor structure according to another embodiment of the present disclosure. As shown in FIG. 17, an insulating material 207 is disposed between the first electrode 205 and a sidewall of the filling groove 2051 to achieve insulation blocking between the first electrode 205 and the second semiconductor layer 203, and between the first electrode 205 and the active layer 202, and to connect the first electrode 205 with the first semiconductor layer 201.

In this embodiment, the insulating material 207 may be silicon dioxide or silicon nitride, or any other applicable insulating material, which is not limited to the present disclosure. Specifically, the insulating material 207, which can play a role of electrical blocking, may be directly formed on the sidewall of the filling groove 2051 through chemical vapor deposition or other methods, to achieve necessary electrical blocking, without filling, etching, or other processes.

Furthermore, the material of the first electrode 205 or the second electrode 206 may be a metal such as gold, copper, silver, zinc, platinum, tantalum, titanium, aluminum, tungsten, nickel, or multiple metal layers, which is not limited to the present disclosure.

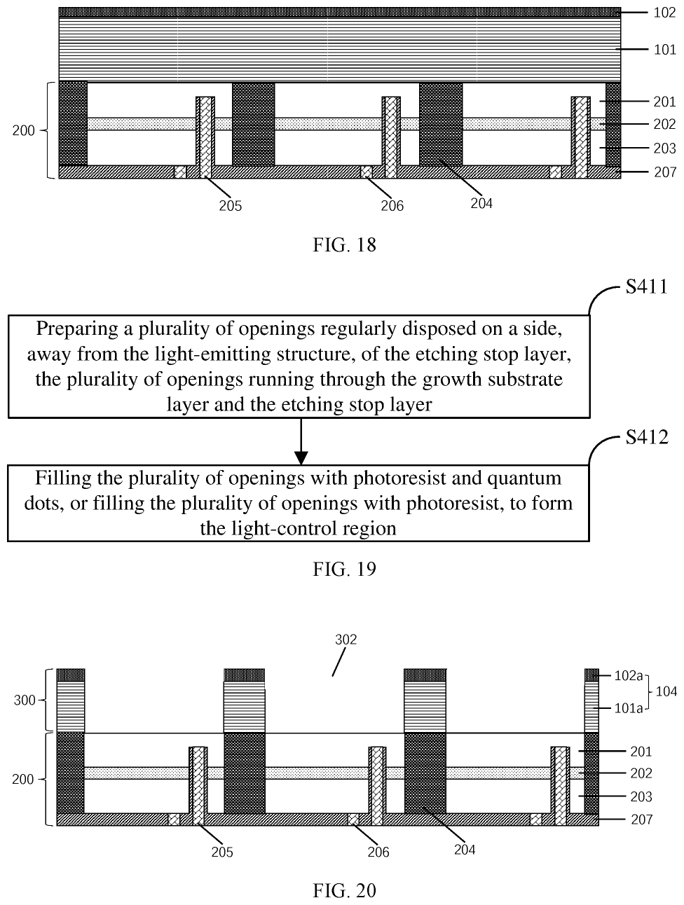

Step S3: Etching the substrate 100 from a side, away from the growth substrate layer 101, to the etching stop layer 102 (as shown in FIG. 18).

Specifically, while etching the substrate 100, the composition of Ge element is monitored in real-time. When Ge signal from the substrate 100 is detected (etching reaches the etching stop layer 102), the action of stopping etching is executed to prevent over etching and obtain the semiconductor structure as shown in FIG. 18. By designing the etching stop layer 102, the etching accuracy of etching to the etching stop layer 102 may be ensured, and the thickness of the remaining substrate is controlled.

Step S4: Forming a light-control layer 300 by forming a plurality of light-control regions 301 regularly disposed in the etching stop layer 102 and the growth substrate layer 101, where the light-control layer 300 further includes a substrate structure 104 disposed between adjacent two light-control regions 301, and the substrate structure 104 includes the growth substrate layer structure 101a and the etching stop layer structure 102a stacked along a direction away from the light-emitting structure, and one light-control region 301 corresponds to at least one light-emitting unit (as shown in FIG. 1).

The substrate structure 104 is composed of a part of the etching stop layer 102 and the growth substrate layer 101 that does not form the light-control region 301. By directly using a part of the etching stop layer 102 and the growth substrate layer 101, namely the substrate structure 104, as a light blocking wall between the plurality of light-control regions 301, the emit direction of light can be controlled and light crosstalk can be avoided. There is no need to prepare an additional light blocking wall after preparing the light-control region to avoid light crosstalk between the plurality of light-control regions, thereby simplifying the manufacturing process.

In some embodiments, as shown in FIG. 19, Step S4 includes the following steps.

Step S411: Preparing a plurality of openings 302 regularly disposed on a side, away from the light-emitting structure 200, of the etching stop layer 102, the plurality of openings 302 running through the growth substrate layer 101 and the etching stop layer 102 (as shown in FIG. 20).

Step S412: Filling the plurality of openings 302 with photoresist and quantum dots, or filling the plurality of openings 302 with photoresist, to form the light-control region 301 (as shown in FIG. 2a to FIG. 2c).

The quantum dots include at least one of red quantum dots, green quantum dots, and blue quantum dots.

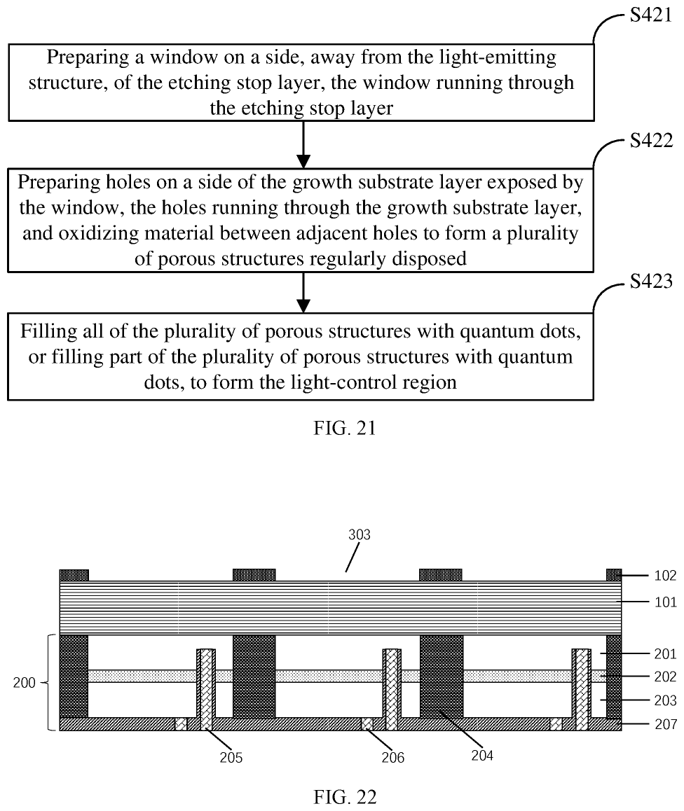

In some embodiments, as shown in FIG. 21, Step S4 includes the following steps.

Step S421: Preparing a window 303 on a side, away from the light-emitting structure 200, of the etching stop layer 102, the window 303 running through the etching stop layer 102 (as shown in FIG. 22).

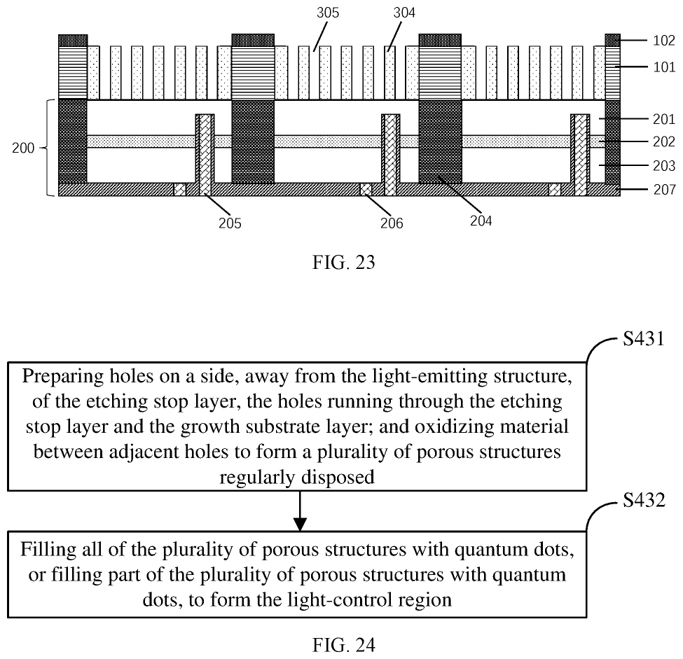

Step S422: Preparing holes 305 on a side of the growth substrate layer 101 exposed by the window 303, the holes 305 running through the growth substrate layer 101, and oxidizing material between adjacent holes 305 to form a plurality of porous structures 304 regularly disposed (as shown in FIG. 23).

In this embodiment, the porous structure 304 is a single layer structure, and the porous structure 304 is a porous silicon oxide layer 3041.

Step S423: Filling all of the plurality of porous structures 304 with quantum dots, or filling part of the plurality of porous structures 304 with quantum dots, to form the light-control region 301 (as shown in FIG. 3).

The material of the growth substrate layer 101 is silicon, and the preparation of the holes 305 in the growth substrate layer 101 is the preparation of porous silicon material. The present disclosure is not limited to the preparation method of porous silicon, and any preparation method, known by those skilled in the art, that can obtain porous silicon can be used in the present disclosure, such as electrochemical corrosion method (or anodic oxidation method), chemical vapor corrosion method, hydrothermal corrosion method, chemical corrosion method (or staining method), and so on. The preferred method for preparing the holes 305 can be electrochemical corrosion method, for example, using a platinum wire or graphite as a cathode, using a monocrystalline silicon as an anode, and performing electrochemical corrosion in a mixed solution containing HF acid to prepare the holes 305. The electrochemical corrosion method does not need electrodes and autoclaves, so the operation process is safe and convenient, and easy to combine with current industrial production facilities.

In some embodiments, as shown in FIG. 24, Step S4 includes the following steps.

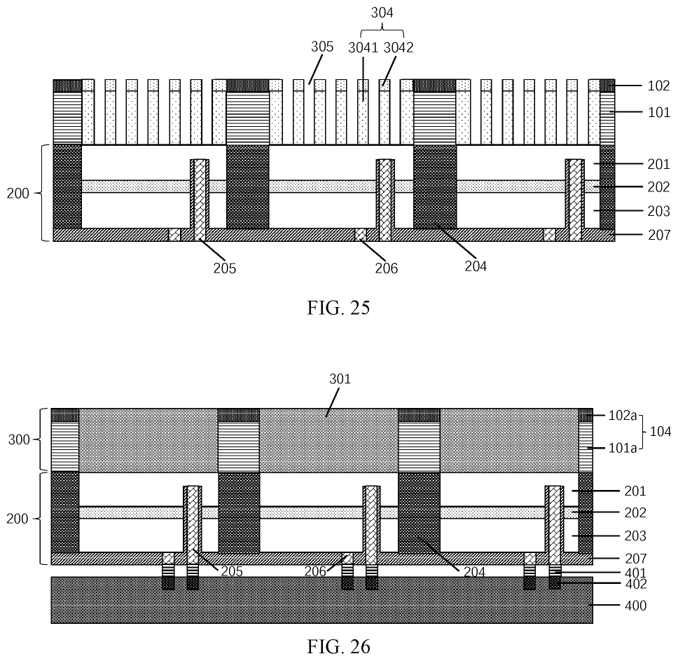

Step S431: Preparing holes 305 on a side, away from the light-emitting structure 200, of the etching stop layer 102, the holes 305 running through the etching stop layer 102 and the growth substrate layer 101; and oxidizing material between adjacent holes 305 to form a plurality of porous structures 304 regularly disposed (as shown in FIG. 25).

In this embodiment, the porous structure 304 is a double-layer structure, and the porous structure 304 includes a porous silicon oxide layer 3041 and a porous silicon germanium oxide layer 3042 disposed on a side, away from the light-emitting structure 200, of the porous silicon oxide layer 3041.

Step S432: Filling all of the plurality of porous structures 304 with quantum dots, or filling part of the plurality of porous structures with quantum dots, to form the light-control region 301 (as shown in FIG. 4).

The quantum dots include at least one of red quantum dots, green quantum dots, and blue quantum dots. By setting the plurality of light-control regions 301 and the substrate structure 104, uniform light output, good directionality, high light extraction rate for each light-control region 301 may be ensured, and light crosstalk may be avoided. By adsorbing the quantum dots utilizing porous structure 304, full color display can be achieved, thereby improving resolution, simplifying production process, and saving costs.

The material of the growth substrate layer 101 is silicon, the material of the etching stop layer 102 is silicon germanium, and the preparation of the holes 305 in the growth substrate layer 101 and the etching stop layer 102 is the preparation of porous silicon and porous silicon germanium material. The present disclosure is not limited to the preparation method of porous silicon and porous silicon germanium material, and any preparation method, known by those skilled in the art, that can obtain porous silicon and porous silicon germanium can be used in the present disclosure, such as electrochemical corrosion method (or anodic oxidation method), chemical vapor corrosion method, hydrothermal corrosion method, chemical corrosion method (or staining method), and so on. The preferred method for preparing the holes 305 can be electrochemical corrosion, for example, using a platinum wire or graphite as a cathode, using a monocrystalline silicon as an anode, and performing electrochemical corrosion in a mixed solution containing HF acid to prepare the holes 305. The electrochemical corrosion method does not need electrodes and autoclaves, so the operation process is safe and convenient, and easy to combine with current industrial production facilities.

The present disclosure provides a light-emitting device including a semiconductor structure according to any one embodiment above and a driving circuit. The driving circuit is connected with the semiconductor structure to drive the semiconductor structure to emit light.

FIG. 26 is a schematic diagram of a light-emitting device according to an embodiment of the present disclosure. A semiconductor structure according to the embodiment of the present disclosure can emit light under the drive of an external driving circuit 400, as shown in FIG. 26, specifically, a first electrode 205 and a second electrode 206 may be connected with an electrode bonding pad 402 in the external driving circuit 400 through a conductive structure 401. The driving circuit 400 may be made into an active or passive driving form. The active driving form has a fast response speed and is not limited by the number of scanning electrodes, and each pixel unit can be individually addressed and controlled, which make it suitable for most applications. The passive driving form, which uses progressive scanning for display, has lower production costs and technical barriers, but cannot achieve high-resolution display well.

The present disclosure provides a semiconductor structure, a manufacturing method of a semiconductor structure, and a light-emitting device. The semiconductor structure includes: a light-emitting structure including a plurality of light-emitting units, where an insulating structure is disposed between adjacent two light-emitting units; and a light-control layer, disposed on a side of the light-emitting structure, including a plurality of light-control regions regularly disposed and a substrate structure disposed between adjacent two light-control regions. One light-control region corresponds to at least one light-emitting unit. The substrate structure includes a growth substrate layer structure and an etching stop layer structure stacked along a direction away from the light-emitting structure.

On the one hand, the etching stop layer structure disclosed can effectively control the thickness of the remaining substrate after thinning, reduce the overall thickness of the device, protect the light-emitting structure during the thinning process, and reduce the damage to the epitaxial structure caused by substrate stripping, thereby improving the application performance of semiconductor structures. On the other hand, the etching stop layer structure and the growth substrate layer structure can be served as a light blocking wall between adjacent two light-control regions, thereby ensuring uniform light output, good directionality, high light extraction rate for each light-control region, and further avoiding light crosstalk.

It should be understood that the term “including” and its variations used in the present disclosure are open-ended, that is, “including but not limited to”. The term “one embodiment” means “at least one embodiment”, the term “another embodiment” means “at least one other embodiment”. In this specification, the schematic expressions of the above terms do not necessarily refer to the same embodiments or examples. Moreover, the specific features, structures, materials, or characteristics described can be combined in an appropriate manner in any one or more embodiments or examples. In addition, those skilled in the art may combine and integrate the different embodiments or examples described in this specification, as well as the features of different embodiments or examples, without contradiction.

The above-mentioned embodiments are only the preferred embodiments of the present disclosure, and not intended to limit the protection scope of the present disclosure. Any modification, equivalent replacement, improvement and so on that made in the spirit and principle of the present disclosure shall fall into the protection scope of the present disclosure.

What is claimed is:

1. A semiconductor structure, comprising:
a light-emitting structure comprising a plurality of light-emitting units, wherein an insulating structure is disposed between adjacent two light-emitting units; and
a light-control layer, disposed on a side of the light-emitting structure, comprising a plurality of light-control regions regularly disposed and a substrate structure disposed between adjacent two light-control regions, one light-control region corresponding to at least one light-emitting unit,
wherein the substrate structure comprises a growth substrate layer structure and an etching stop layer structure stacked along a direction away from the light-emitting structure.

2. The semiconductor structure according to claim 1, wherein a material of the growth substrate layer structure comprises silicon, and a material of the etching stop layer structure comprises silicon germanium.

3. The semiconductor structure according to claim 1, wherein a thickness of the growth substrate layer structure is less than or equal to 50 μm.

4. The semiconductor structure according to claim 1, wherein a thickness of the etching stop layer structure is 10-100 nm.

5. The semiconductor structure according to claim 1, wherein the light-control region comprises an opening filled with photoresist and quantum dots.

6. The semiconductor structure according to claim 5, wherein a surface of the light-emitting structure exposed by the opening has an uneven structure.

7. The semiconductor structure according to claim 1, wherein the light-control region comprises a porous structure filled with quantum dots.

8. The semiconductor structure according to claim 7, wherein the porous structure is a single-layer structure, and the porous structure is a porous silicon oxide layer.

9. The semiconductor structure according to claim 7, wherein the porous structure is a double-layer structure, and the porous structure comprises a porous silicon oxide layer and a porous silicon germanium oxide layer disposed on a side, away from the light-emitting structure, of the porous silicon oxide layer.

10. The semiconductor structure according to claim 1, wherein a sidewall of the light-control region is inclined, so that an equivalent diameter of the light-control region increases along a direction of light travel.

11. The semiconductor structure according to claim 1, wherein a light reflection layer is disposed on a sidewall of the light-control region.

12. A light-emitting device, comprising: the semiconductor structure according to claim 1 and a driving circuit, wherein the driving circuit is connected with the semiconductor structure to drive the semiconductor structure to emit light.

13. A manufacturing method of a semiconductor structure, comprising:
S1: providing a substrate comprising a support substrate layer, an etching stop layer, and a growth substrate layer stacked in sequence;
S2: forming a light-emitting structure on the growth substrate layer, wherein the light-emitting structure comprises a plurality of light-emitting units, and an insulating structure is disposed between adjacent two light-emitting units;
S3: etching the substrate from a side, away from the growth substrate layer, to the etching stop layer; and
S4: forming a light-control layer by forming a plurality of light-control regions regularly disposed in the etching stop layer and the growth substrate layer, wherein the light-control layer further comprises a substrate structure disposed between adjacent two light-control regions, and the substrate structure comprises the growth substrate layer structure and the etching stop layer structure stacked along a direction away from the light-emitting structure, and one light-control region corresponds to at least one light-emitting unit.

14. The manufacturing method according to claim 13, wherein the step S4 comprises:
S411: preparing a plurality of openings regularly disposed on a side, away from the light-emitting structure, of the etching stop layer, the plurality of openings running through the growth substrate layer and the etching stop layer; and
S412: filling the plurality of openings with photoresist and quantum dots, or filling the plurality of openings with photoresist, to form the light-control region.

15. The manufacturing method according to claim 14, wherein the quantum dots comprise at least one of red quantum dots, green quantum dots, and blue quantum dots.

16. The manufacturing method according to claim 13, wherein the step S4 comprises:
S421: preparing a window on a side, away from the light-emitting structure, of the etching stop layer, the window running through the etching stop layer;
S422: preparing holes on a side of the growth substrate layer exposed by the window, the holes running through the growth substrate layer; and oxidizing material between adjacent holes to form a plurality of porous structures regularly disposed; and
S423: filling all of the plurality of porous structures with quantum dots, or filling part of the plurality of porous structures with quantum dots, to form the light-control region.

17. The manufacturing method according to claim 16, wherein the porous structure is a single-layer structure, and the porous structure is a porous silicon oxide layer.

18. The manufacturing method according to claim 13, wherein the step S4 comprises:
S431: preparing holes on a side, away from the light-emitting structure, of the etching stop layer, the holes running through the etching stop layer and the growth substrate layer; and oxidizing material between adjacent holes to form a plurality of porous structures regularly disposed; and
S432: filling all of the plurality of porous structures with quantum dots, or filling part of the plurality of porous structures with quantum dots, to form the light-control region.

19. The manufacturing method according to claim 18, wherein the porous structure is a double-layer structure, and the porous structure comprises a porous silicon oxide layer and a porous silicon germanium oxide layer disposed on a side, away from the light-emitting structure, of the porous silicon oxide layer.

20. The manufacturing method according to claim 13, wherein a sidewall of the light-control region is inclined, so that an equivalent diameter of the light-control region increases along a direction of light travel.
